(19) United States
(12) Patent Application Publication
(10) Pub. No.: US 2011/0089553 A1
(43) Pub. Date: Apr. 21, 2011

(54) STACK-TYPE SOLID-STATE DRIVE

(75) Inventors: Tae Hyun KIM, Cheonan (KR); Gyu Han KIM, Pyeongtaek (KR)

(73) Assignee: STS SEMICONDUCTOR & TELECOMMUNICATIONS CO., LTD., Cheonan (KR)

(21) Appl. No.: 12/637,755

(22) Filed: Dec. 15, 2009

(30) Foreign Application Priority Data
Oct. 15, 2009 (KR) 10-2009-0098413

(51) Int. Cl. H01L 25/16; H01L 23/52

(52) U.S. Cl. 257/686; 257/693; 257/723; 257/E23.141; 257/E25.029

(57) ABSTRACT

Provided are a stack-type solid-state drive (SSD) capable of reducing a size thereof by mounting semiconductor chips in a recess region formed in a substrate, and a method of fabricating the stack-type SSD. The stack-type SSD includes a substrate including one or more recess regions; one or more passive electronic elements mounted in the one or more recess regions; one or more control semiconductor chips mounted in the one or more recess regions; one or more non-volatile memory semiconductor chips mounted on a first surface of the substrate so as to overlap the one or more passive electronic elements, the one or more control semiconductor chips, or all the passive electronic elements and the control semiconductor chips; and an external connection terminal located on a side of the substrate.

### CROSS-REFERENCE TO RELATED PATENT APPLICATION

This application claims the benefit of Korean Patent Application No. 10-2009-0098413, filed on Oct. 15, 2009, in the Korean Intellectual Property Office, the disclosure of which is incorporated herein in its entirety by reference.

### BACKGROUND OF THE INVENTION

1. Field of the Invention

The present invention relates to a stack-type solid-state drive (SSD), and more particularly, to a stack-type SSD having a small size by mounting semiconductor chips in a recess region formed in a substrate.

2. Description of the Related Art

Recently, computing devices have been essential for managing a large amount of information. As the functions of hardware in computing devices have been improved, a capacity of data or programs used in the computing devices has rapidly increased. In computing devices, a hard disk is generally used as a data memory device. Since a hard disk in one of these computing devices records and reproduces data via a physical contact with a rotating disk, the hard disk has high power consumption, there is a limitation in reducing the size of the computing device, and the computing device may be damaged due to vibration of the hard disk. Recently, solid-state drives (SSDs), including a non-volatile memory, have been used as a hard disk. However, in one of these SSDs, memory chips and control chips are mounted on a substrate plane, and thus, there is a limitation in reducing the entire size of the computing device.

### SUMMARY OF THE INVENTION

The present invention provides a stack-type solid-state drive (SSD) with a reduced size by mounting semiconductor chips in a recess region formed in a substrate.

The present invention also provides a method of manufacturing a stack-type SSD having a reduced size by mounting semiconductor chips in a recess region formed in a substrate.

According to an aspect of the present invention, there is provided a stack-type solid-state drive (SSD) including: a substrate including one or more recess regions; one or more passive electronic elements mounted in the one or more recess regions; one or more control semiconductor chips mounted in the one or more recess regions; one or more non-volatile memory semiconductor chips mounted on a first surface of the substrate so as to overlap the one or more passive electronic elements, the one or more control semiconductor chips, or all the passive electronic elements and the control semiconductor chips; and an external connection terminal located on a side of the substrate.

In some embodiments of the present invention, the stack-type SSD may further include one or more buffer memory semiconductor chips mounted in the one or more recess regions. In addition, the one or more buffer memory semiconductor chips may include a dynamic random access memory (DRAM), a static random access memory (SRAM), or both of the DRAM and SRAM.

In some embodiments of the present invention, at least some of the one or more passive electronic elements and the one or more control semiconductor chips may be mounted in different recess regions from each other among the one or more recess regions.

In some embodiments of the present invention, at least some of the one or more passive electronic elements, the one or more control semiconductor chips, and the one or more buffer memory semiconductor chips may be mounted in different recess regions from each other among the one or more recess regions.

In some embodiments of the present invention, the one or more recess regions further comprise a first wiring pattern formed in the recess regions, and the one or more passive electronic elements, the one or more control semiconductor chips, or all the passive electronic elements and the control semiconductor chips may be electrically connected to the first wiring pattern via a first connection member. In addition, the first connection member may include a bonding wire, a solder ball, a flip-chip bonding member, a bump, or a conductive via. In addition, the first connection member may have a height so as not to protrude from the one or more recess regions.

In some embodiments of the present invention, the substrate may further include a second wiring pattern formed in the first surface, and the one or more non-volatile memory semiconductor chips may be electrically connected to the second wiring pattern via a third connection member. In addition, the third connection member may include a bonding wire, a solder ball, a flip-chip bonding member, a bump, or a conductive via.

In some embodiments of the present invention, the one or more non-volatile memory semiconductor chips may be semiconductor dies or semiconductor packages.

In some embodiments of the present invention, the one or more non-volatile memory semiconductor chips may be NAND flash memories, phase-change random access memories (PRAMs), resistive RAMs (RRAMs), ferroelectric RAMs (FeRAMs), or magnetic RAMs (MRAMs).

In some embodiments of the present invention, the one or more non-volatile memory semiconductor chips may include a plurality of non-volatile memory semiconductor chips which are stacked.

In some embodiments of the present invention, the stack-type SSD may further include one or more additional non-volatile memory semiconductor chips mounted in the one or more recess regions.

In some embodiments of the present invention, the substrate may have a multi-layered structure. In addition, the substrate may include an epoxy resin, a polyimide resin, a bismaleimide triazine (BT) resin, frame retardant (FR)-4, FR-6, ceramic, silicon, or glass.

In some embodiments of the present invention, the external connection terminal may be a serial advanced technology attachment (SATA), a parallel advanced technology attachment (PATA), a universal serial bus (USB), or an integrated drive electronics (IDE).

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram of a stack-type solid-state drive (SSD) connected to a host, according to an embodiment of the present invention;

FIG. 2 is a top view of a stack-type SSD connected to a host, according to an embodiment of the present invention;

FIG. 3 is a cross-sectional view of the stack-type SSD taken along line III-III′ of FIG. 2;

FIGS. 4A through 4D are cross-sectional views illustrating a method of manufacturing the stack-type SSD of FIG. 1, according to an embodiment of the present invention;

FIGS. 5 through 10 are cross-sectional views of stack-type SSD s according to embodiments of the present invention;

FIG. 11 is a cross-sectional view of a substrate in which a recess region is formed, according to an embodiment of the present invention; and

FIG. 12 is a cross-sectional view of a substrate in which a recess region is formed, according to an embodiment of the present invention.

### DETAILED DESCRIPTION OF THE INVENTION

Reference will now be made in detail to exemplary embodiments, examples of which are illustrated in the accompanying drawings. However, exemplary embodiments are not limited to the embodiments illustrated hereinafter, and the embodiments herein are rather introduced to provide easy and complete understanding of the scope and spirit of exemplary embodiments. In the drawings, the thicknesses of layers and regions are exaggerated for clarity.

It will be understood that when an element, such as a layer, a region, or a substrate, is referred to as being “on,” “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of exemplary embodiments.

Spatially relative terms, such as “above,” “upper,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “above” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes may be not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the exemplary embodiments of the inventive concept will be described in detail with reference to the accompanying drawings. In the drawings, variations from the shapes of the illustrations as a result, for example, of manufacturing techniques and/or tolerances, are to be expected. Thus, the example embodiments should not be construed as limited to the particular shapes of regions illustrated herein but may be to include deviations in shapes that result, for example, from manufacturing.

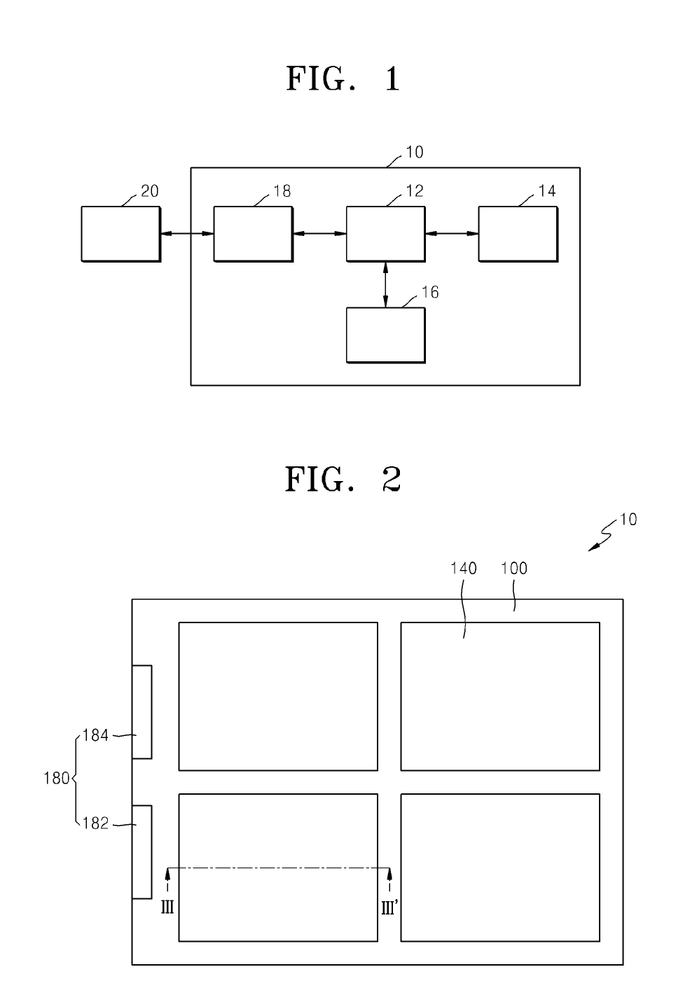

FIG. 1 is a block diagram of a stack-type SSD 10 connected to a host 20, according to an embodiment of the present invention.

Referring to FIG. 1, the stack-type SSD 10 includes a memory 14, a controller 12, a buffer memory 16, and an external connector 18. The memory 14 stores data, and may be a non-volatile memory, for example, a flash memory, which may store the data even when an electric power is not supplied to the memory 14. The buffer memory 16 temporarily stores commands or data while the stack-type SSD 10 operates. The buffer memory 16 may include a dynamic random access memory (DRAM), a static random access memory (SRAM), or both of the DRAM and SRAM. An internal battery system (not shown) may supply electric power to the buffer memory 16. The internal battery system can supply the electric power to the buffer memory 16 even when a main power is turned off, and accordingly, the buffer memory 16 may store the data. The controller 12 controls accesses to the data stored in the memory 14. In addition, the controller 12 may transmit input commands or the data stored in the memory 14 to the buffer memory 16, or transmit the data stored in the buffer memory 16 to the memory 14 to store the data in the memory 14. The controller 12 may be configured as an additional controlling semiconductor chip such as an application-specific integrated circuit (ASIC), or may be a controlling program stored in a system region of the memory 14. The controller 12 may be designed to be automatically driven by an operating system of the host 20, when the stack-type SSD 10 is connected to the host 20, for example. In this case, the controller 12 may include a script for automatic driving and an application program which may be executed in the host 20. The external connector 18 connects the stack-type SSD 10 to the host 20. For example, the external connector 18 may be a serial advanced technology attachment (SATA), a parallel advanced technology attachment (PATA), a universal serial bus (USB), or an Integrated Drive Electronics (IDE), and may be electrically connected to the host 20 by being inserted directly into a socket (not shown) of the host 20 or by being connected to the socket (not shown) of the host 20 through a cable. If necessary, the external connector 18 may be electrically connected to the host 20 via an additional reader (not shown).

When the stack-type SSD 10 is connected to the host 20 via the external connector 18, an enumeration operation is performed. The enumeration operation is a process of determining an endpoint type, the number, or kind of the stack-type SSD 10 by the host 20. The host 20 aligns an address to the stack-type SSD 10, and receives a device descriptor and a configuration descriptor from the stack-type SSD 10 to prepare the data transmission. The host 20 of the present embodiment may be any kind of device including a calculator, a memory, a controller, and an input/output unit, for example, a computer, a personal computer (PC), a portable computer, a mobile phone, a smart phone, a personal digital assistant (PDA), a moving picture experts group layer 3 (MP3) player, a navigation device, or a portable multimedia player (PMP).

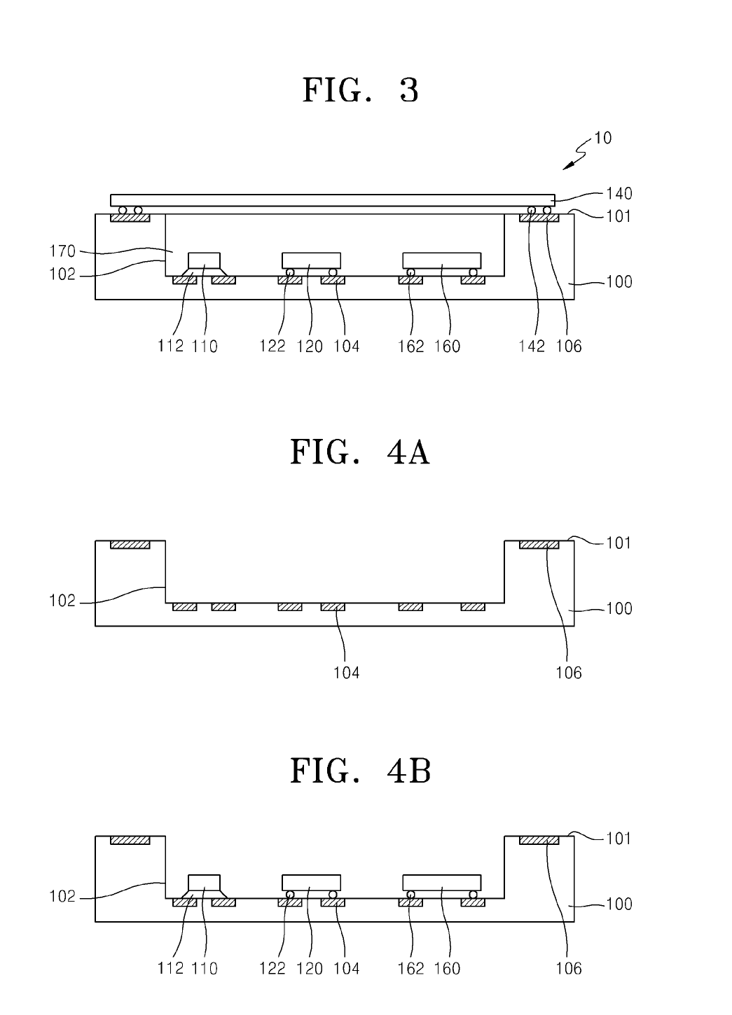

FIG. 2 is a top view of the stack-type SSD 10 according to the embodiment of the present invention. FIG. 3 is a cross-sectional view of the stacking-type solid state drive 10 taken along line III-III′ of FIG. 2.

Referring to FIGS. 2 and 3, the stack-type SSD 10 includes a substrate 100, four non-volatile memory semiconductor chips 140 mounted on the substrate 100, and an external connection terminal 180 located on a side of the substrate 100 for electrically connecting to an external device. In the present embodiment, the stack-type SSD 10 includes four non-volatile memory semiconductor chips 140; however, the present invention is not limited thereto, and the stack-type SSD 10 can include one or more non-volatile memory semiconductor chips 140. In addition, the stack-type SSD 10 may include one or more passive electronic elements 110 and one or more control semiconductor chips 120, and may further include one or more buffer memory semiconductor chips 160 optionally. FIG. 3 illustrate one passive electronic element 110, one control semiconductor chip 120, and one buffer memory semiconductor chip 180, however, the present invention is not limited thereto. The control semiconductor chip 120, the non-volatile memory semiconductor chip 140, the buffer memory semiconductor chip 160, and the external connection terminal 180 may respectively correspond to the controller 12, the memory 14, the buffer memory 16, and the external connector 18 of FIG. 1.

The substrate 100 may be formed of an epoxy resin, a polyimide resin, a bismaleimide triazine (BT) resin, frame retardant-4 (FR-4), FR-6, ceramic, silicon, or glass; however, the present invention is not limited to these examples. The substrate 100 may have a single-layered structure or a multi-layered structure including wiring patterns therein. For example, the substrate 100 may be a rigid substrate, may be formed of a plurality of rigid substrates that are attached to each other, or may be formed of a thin flexible printed circuit board (PCB) and a rigid substrate attached to each other. The plurality of rigid substrates, or the PCB attached to each other may respectively include wiring patterns therein. In addition, the substrate 100 may be a low temperature co-fired ceramic (LTCC) substrate which is fabricated by stacking a plurality of ceramic layers and includes wiring patterns therein. The substrate 100 may be formed with a molding method.

The substrate 100 includes a recess region 102. In the present embodiment of FIG. 3, the stack-type SSD 10 include one recess region 102; however, the present invention is not limited thereto, and the stack-type SSD 10 can include a plurality of recess regions 102.

A first wiring pattern 104 may be located in the recess region 102. In addition, a second wiring pattern 106 may be formed in a first surface 101 of the substrate 100. Although it is not shown in FIG. 3, the first wiring pattern 104 and the second wiring pattern 106 may be electrically connected to each other by an electric connecting member, for example, conductive vias (not shown), and may be electrically connected to the external connection terminal 180, respectively. In addition, the first wiring pattern 104 and/or the second wiring pattern 106 may include a metal material, for example, copper (Cu), aluminum (Al), gold (Au), silver (Ag), platinum (Pt), nickel (Ni), palladium (Pd), rubidium (Ru), or an alloy thereof. In addition, the first wiring pattern 104 and/or the second wiring pattern 106 may include a plurality of layers, and/or a metal having a high oxidation resistance, for example, Au, plated thereon. However, the present invention is not limited thereto.

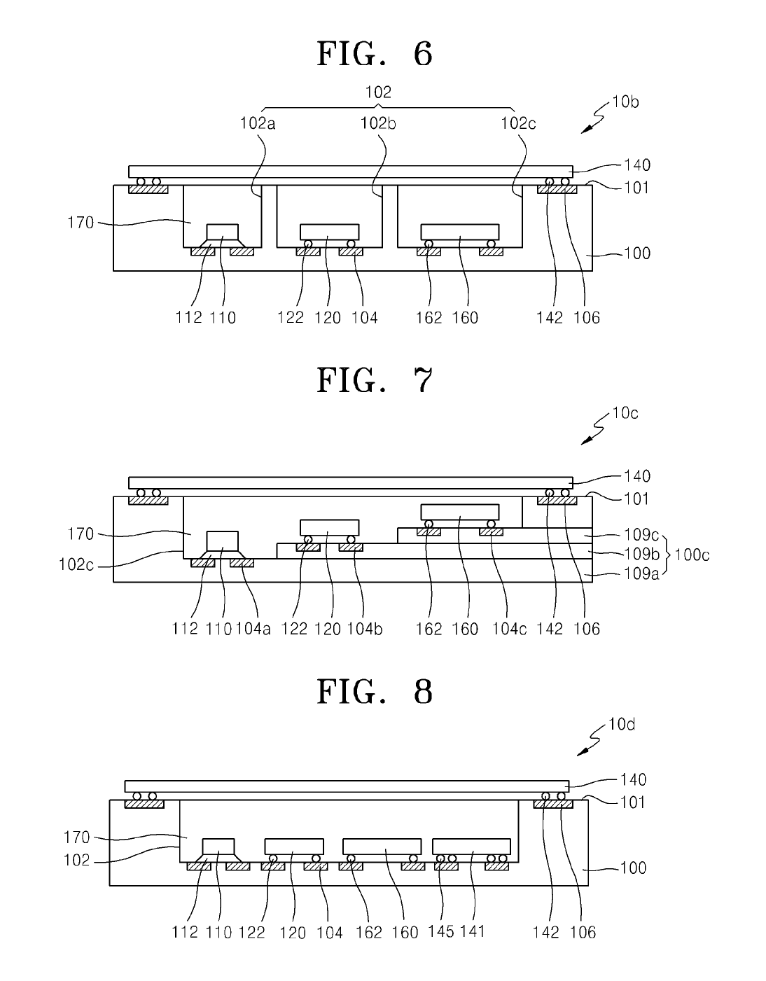

The passive electronic element 110 and the control semiconductor chip 120 are mounted in the recess region 102. In addition, the buffer memory semiconductor chip 160 is further mounted in the recess region 102. The passive electronic element 110 is electrically connected to the first wiring pattern 104 via a passive electronic element connecting member 112. The control semiconductor chip 120 is electrically connected to the first wiring pattern 104 formed in the recess region 102 via a first connecting member 122. The buffer memory semiconductor chip 160 is electrically connected to the first wiring pattern 104 via a second connecting member 162. The relative relations or the number of passive electronic elements 110, control semiconductor chips 120, and buffer memory semiconductor chips 160 shown in FIG. 3 are examples, and the present invention is not limited thereto. For example, a plurality of passive electronic elements 110, a plurality of control semiconductor chip 120, and a plurality of buffer memory semiconductor chips 160 may be formed, and may be arranged differently from the arrangement shown in FIG. 3 in the recess region 102. In addition, as shown in FIG. 6, as will be described later, the passive electronic element 110, the control semiconductor chip 120, and the buffer memory semiconductor chip 160 may be respectively mounted in recess regions 102a, 102b, and 102c (refer to FIG. 6) which are separate from each other. If necessary, the passive electronic element 110, the control semiconductor chip 120, and the buffer memory semiconductor chip 160 may be sealed by a sealing material 170.

The passive electronic element 110 may be a resistive element, an inductor element, a capacitor element, or a switch element, and the passive electronic element connecting member 112 may be a solder ball.

The control semiconductor chip 120 controls communications between the stack-type SSD 10 and the host 20, and controls the operations of programming, reading, and erasing data in the non-volatile memory semiconductor chip 140. In addition, the control semiconductor chip 120 may be a semiconductor die or a semiconductor package.

The buffer memory semiconductor chip 160 may include a DRAM, an SRAM, or both of them. In addition, the buffer memory semiconductor chip 160 may be a semiconductor die or a semiconductor package.

The first connecting member 122 and the second connecting member 162 may be solder balls, bonding wires, flip-chip bonding members, bumps, conductive vias, or combinations thereof.

The non-volatile memory semiconductor chip 140 is mounted on the first surface 101 of the substrate 100. That is, the non-volatile memory semiconductor chip 140 may be mounted on the passive electronic element 110, the control semiconductor chip 120, the buffer memory semiconductor chip 160 mounted in the recess region 102, or the recess region 102 so as to overlap all of the above elements mounted in the recess region 102. The non-volatile memory semiconductor chip 140 is electrically connected to the second wiring pattern 106 which is formed in the first surface 101 of the substrate 100 via a third connecting member 142. The non-volatile memory semiconductor chip 140 may be a non-volatile memory such as a NAND flash memory, a phase-change random access memory (PRAM), a Resistive RAM (RRAM), a Ferroelectric RAM (FeRAM), or a Magnetic RAM (MRAM). In addition, the non-volatile memory semiconductor chip 140 may be a semiconductor die or a semiconductor package.

The external connection terminal 180 may include an electric signal terminal 182 and a power terminal 184. As described above, the electric signal terminal 182 may be electrically connected to the first wiring pattern 104 and/or the second wiring pattern 106. The external connection terminal 180 may be a SATA, a PATA, a USB, or an IDE. In the present embodiment, the stack-type SSD 10 includes one external connection terminal 180; however the present invention is not limited thereto, and the stack-type SSD 10 can include a plurality of external connection terminals 180 of different kinds.

In the stack-type SSD 10 of the present embodiment, the passive electronic element 110, the control semiconductor chip 120, and the buffer memory semiconductor chip 160 are mounted in the recess region 102 of the substrate 100, and thus, the non-volatile memory semiconductor chip 140 may be overlap the passive electronic element 110, the control semiconductor chip 120, and the buffer memory semiconductor chip 160. Accordingly, a size of the stack-type SSD 10 may be reduced. The stack-type SSD 10 may be used as an internal SSD, an external SSD, or an embedded SSD.

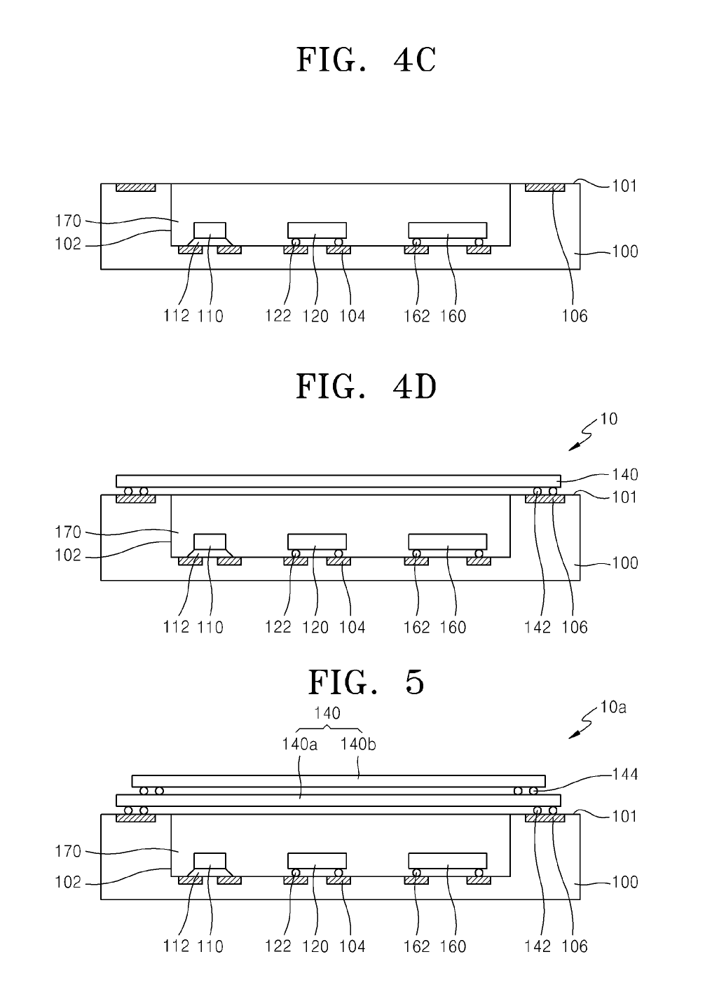

FIGS. 4A through 4D are cross-sectional views illustrating a method of manufacturing the stack-type SSD 10, according to an embodiment of the present invention.

Referring to FIG. 4A, the substrate 100 is prepared including the recess region 102. In the present embodiment, the substrate 100 includes one recess region 102; however the present invention is not limited thereto, and the substrate 100 can include one or more recess regions. The substrate 100 includes the first wiring pattern 104 formed in the recess region 102, and the second wiring pattern 106 formed in the first surface 101 of the substrate 100. The recess portion 102 may be formed by mechanically processing a part of the substrate 100 or chemically etching a part of the substrate 100. In addition, the recess region 102 may be formed by attaching two or more substrate members (not shown), which are processed in advance to form the recess region 102. Otherwise, the recess region 102 may be formed by using a mold having an inversed-shape of the recess region 102 simultaneously when the substrate 100 is formed. The first wiring pattern 104 and/or the second wiring pattern 106 may be formed with a deposition method, a plating method, an attaching method, or a compressing method, and may include a metal material, for example, Cu, Al, Au, Ag, Pt, Ni, Pd, Ru, or an alloy thereof. In addition, the first wiring pattern 104 and the second wiring pattern 106 may be electrically connected to each other via an electric connection member (not shown).

Referring to FIG. 4B, a passive electronic element 110, a control semiconductor chip 120, and a buffer memory semiconductor chip 160 are mounted in the recess region 102 of the substrate 100. In the present embodiment, one passive electronic element 110, one control semiconductor chip 120, and one buffer memory semiconductor chips 160 are mounted in the recess region 102 of the substrate 100; however the present invention is not limited thereto, and one or more passive electronic elements 110, one or more control semiconductor chips 120, and one or more buffer memory semiconductor chips 160 can be mounted in the recess region 102 of the substrate 100. The passive electronic element 110 may be electrically connected to the first wiring pattern 104 via a passive electronic element connection member 112, for example, a solder ball. The control semiconductor chip 120 may be electrically connected to the first wiring pattern 104 via a first connection member 122. The buffer memory semiconductor chip 160 may be electrically connected to the first wiring pattern 104 via a second connection member 162. The passive electronic element 110, the control semiconductor chip 120, and the buffer memory semiconductor chip 160 may not protrude over the first surface 101 of the substrate 100. In addition, in FIG. 4B, the first and second connection members 122 and 162 are solder balls; however, the present invention is not limited thereto. For example, each of the first connection member 122 and the second connection member 162 may be a bonding wire, a flip-chip bonding member, a bump, a conductive via, or a combination thereof. Other examples of the first and second connection members 122 and 162 will be described as follows in detail.

Referring to FIG. 4C, a sealing material 170 that buries the passive electronic element 110, the control semiconductor chip 120, and the buffer memory semiconductor chip 160 in the recess region 102 is optionally formed. The sealing material 170 seals the passive electronic element 110, the control semiconductor chip 120, and the buffer memory semiconductor chip 160. The sealing material 170 protects the passive electronic element 110, the control semiconductor chip 120, the buffer memory semiconductor chip 160, the passive electronic element connection member 112, the first connection member 122, and the second connection member 162 from the external environment. The passive electronic element 110, the control semiconductor chip 120, the buffer memory semiconductor chip 160, the first connection member 122, and the second connection member 162 may not protrude out of the sealing material 170. The sealing material 170 may be an encapsulant material, for example, an epoxy resin or a silicon resin; however, the present invention is not limited thereto.

Referring to FIG. 4D, a non-volatile memory semiconductor chip 140 is mounted on the first surface 101 of the substrate 100. In the present embodiment, one non-volatile memory semiconductor chip 140 is mounted on the first surface 101 of the substrate 100; however the present invention is not limited thereto, and one or more non-volatile memory semiconductor chips 140 can be mounted on the first surface 101 of the substrate 100. The non-volatile memory semiconductor chip 140 is disposed on the recess region 102 in which the passive electronic element 110, the control semiconductor chip 120, and the buffer memory semiconductor chip 160 are mounted, and accordingly, the non-volatile memory semiconductor chip 140 may overlap at least one of the passive electronic element 110, the control semiconductor chip 120, and the buffer memory semiconductor chip 160. The non-volatile memory semiconductor chip 140 may be electrically connected to the second wiring pattern 106 that is formed in the first surface 101 of the substrate 100 via the third connection member 142. In FIG. 4D, the third connection member 142 is a solder ball; however, the present invention is not limited thereto. For example, the third connection member 142 may be a bonding wire, a flip-chip bonding member, a bump, a conductive via, or a combination thereof. Another example of the third connection member 142 will be described as follows in more detail.

FIGS. 5 through 10 are cross-sectional views of stack-type SSDs 10a, 10b, 10c, 10d, 10e, and 10f according to embodiments of the present invention. For convenience, descriptions of the same elements as those of the previous embodiment are not provided here.

Referring to FIG. 5, the stack-type SSD 10a includes non-volatile memory semiconductor chips 140a and 140b which are sequentially stacked on the recess region 102 to overlap each other. The non-volatile memory semiconductor chips 140a and 140b may have the same size or different sizes from each other. As described above, the lower non-volatile memory semiconductor chip 140a may be electrically connected to the second wiring pattern 106 via the third connection member 142. On the other hand, the upper non-volatile memory semiconductor chip 140b may be electrically connected to the lower non-volatile memory semiconductor chip 140a via a fourth connection member 144 such as a solder ball, and may be electrically connected to the second wiring pattern 106 via the third connection member 142. However, the number, size, stacking method, stacking structure, and the electric connection of the non-volatile memory semiconductor chips 140a and 140b are examples, and the present invention is not limited thereto.

Referring to FIG. 6, the stack-type SSD 10b is different from the stack-type SSD 10 of FIG. 3 in that the stack-type SSD 10b includes the separate recess regions 102a, 102b, and 102c respectively including the passive electronic element 110, the control semiconductor chip 120, and the buffer memory semiconductor chip 160. At least some of the passive electronic element 110, the control semiconductor chip 120, and the buffer memory semiconductor chip 160 may be mounted in different recess regions among the plurality of recess regions 102a, 102b, and 102c. For example, in FIG. 6, the passive electronic element 110, the control semiconductor chip 120, and the buffer memory semiconductor chip 160 are mounted respectively in the recess regions 102a, 102b, and 102c.

Referring to FIG. 7, the stack-type SSD 10c is different from the stack-type SSD 10 of FIG. 3 in that a substrate 100c is formed by coupling substrate members 109a, 109b, and 109c to each other. The substrate members 109a, 109b, and 109c are attached to each other to form a recess region 102c. First wiring patterns 104a, 104b, and 104c are respectively formed in the substrate members 109a, 109b, and 109c, and may be electrically connected to each other. The passive electronic element 110 may be mounted on the substrate member 109a, the control semiconductor chip 120 may be mounted on the substrate member 109b, and the buffer memory semiconductor chip 160 may be mounted on the substrate member 109c. However, the present invention is not limited to the above example.

Referring to FIG. 8, the stack-type SSD 10d is different from the stack-type SSD 10 of FIG. 3 in that the stack-type SSD 10d may further include an additional non-volatile memory semiconductor chip 141 mounted in the recess region 102. In the present embodiment, the stack-type SSD 10 includes one additional non-volatile memory semiconductor chip 141; however the present invention is not limited thereto, and the stack-type SSD 10 can include one or more additional non-volatile memory semiconductor chips 141. The additional non-volatile memory semiconductor chip 141 may be the same kind as that of the non-volatile memory semiconductor chip 140, for example, may be a NAND flash memory, a PRAM, an RRAM, a FeRAM, or an MRAM. In addition, the additional non-volatile memory semiconductor chip 141 may be electrically connected to the first wiring pattern 104 and/or the second wiring pattern 106 via a fifth connection member 145. In FIG. 8, the fifth connection member 145 is a solder ball; however, the present invention is not limited thereto. For example, the fifth connection member 145 may be a bonding wire, a flip-chip bonding member, a bump, a conductive via, or a combination thereof.

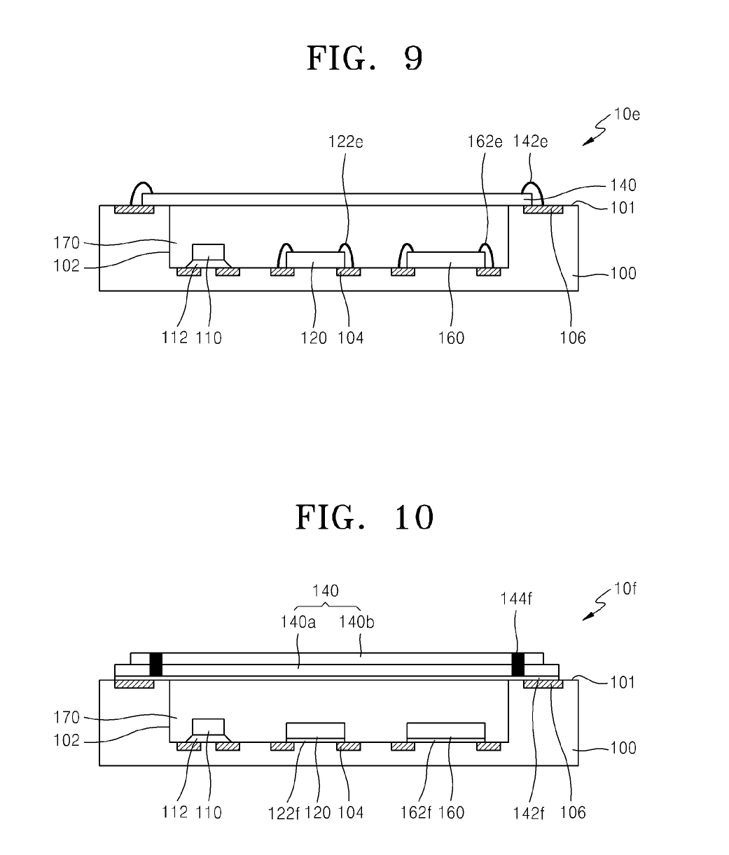

Referring to FIG. 9, the stack-type SSD 10e is different from the stack-type SSD 10 of FIG. 3 in that at least one of a first connection member 122e, a second connection member 162e, and a third connection member 142e is a bonding wire. Here, the first connection member 122e and the second connection member 162e which are formed of bonding wires may be buried in the recess region 102 so as not to protrude over the first surface 101 of the substrate 100. The bonding wires may be formed of Au, Ag, Cu, Al, or an alloy thereof. The bonding wires may be formed in a forward folder loop mode or a reverse loop mode method. The control semiconductor chip 120 and/or the buffer memory semiconductor chip 160 may be adhered to the substrate 100 in the recess region 102 of the substrate 100 with an adhesive member (not shown) such as a liquid adhesive or an adhesive tape. In addition, the non-volatile memory semiconductor chip 140 may be adhered to the first surface 101 of the substrate 100 by an adhesive member (not shown) such as the liquid adhesive or the adhesive tape.

Referring to FIG. 10, the stack-type SSD 10f is different from the stack-type SSD 10 of FIG. 3 and the stack-type SSD 10a of FIG. 5 in that at least one of a first connection member 122f, a second connection member 162f, and a third connection member 142f is a flip-chip bonding member. In addition, non-volatile memory semiconductor chips 140a and 104b may be connected to each other via a fourth connection member 144f, which is a conductive via.

One of ordinary skill would appreciate that the technical features of the stack-type SSDs 10, 10a, 10b, 10c, 10d, 10e, and 10f described with reference to FIGS. 3, and 5 through 10 may be combined together. In the described embodiments above, the non-volatile memory semiconductor chip 140 may include the non-volatile memory semiconductor chips 140a and 140b as shown in FIG. 5. In addition, in the described embodiments above, the recess regions 102a, 102b, and 102c may be formed as shown in FIG. 6. In addition, in the described embodiments above, the substrate 100 may include the multi-layered structure in which the substrate members 109a, 109b, and 109c are coupled to each other as shown in FIG. 7. Also, in the described embodiments above, the additional non-volatile memory semiconductor chip 141 mounted in the recess region 102 may further formed in the recess region 102 as shown in FIG. 8. In addition, the first connection member 122, 122e, or 122f, the second connection member 162, 162e, or 162f, and the third connection member 142, 142e, or 142f are examples, and the present invention is not limited to these examples. All kinds of conductive connection members known in the art may be used as the first, second, and third connection members. In addition, each of the first connection member 122, 122e, or 122f, the second connection member 162, 162e, or 162f, and the third connection member 142, 142e, or 142f may be formed of the combination of the bonding wire, the solder ball, the bump, the flip-chip bonding member, and the conductive via. Also, the fourth connection member 144 or 144f may be formed of the combination of the bonding wire, the solder ball, the bump, the flip-chip bonding member, and the conductive via.

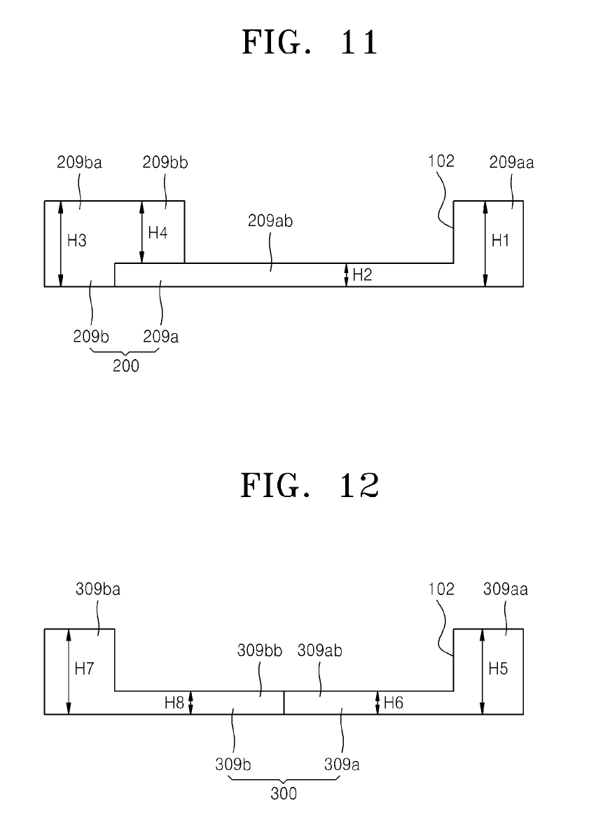

FIG. 11 is a cross-sectional view of a substrate 200 in which a recess region 102 is formed, according to another embodiment of the present invention.

Referring to FIG. 11, the substrate 200 includes a first substrate member 209a and a second substrate member 209b, which are assembled with each other to form the recess region 102. The first substrate member 209a has a first end portion 209aa having a first height H1 and a second end portion 209ab having a second height H2 that is lower than the first height H1. The second end portion 209ab may be formed by chemically or mechanically processing a part of the first substrate member 209a. In addition, the second substrate member 209b has a third end portion 209ba having a third height H3 and a fourth end portion 209bb having a fourth height H4 that is lower than the third height H3. The fourth end portion 209bb may be formed by chemically etching or mechanically processing a part of the second substrate member 209b. In addition, the firth height H1 and the third height H3 may be equal to each other. The first and second substrate members 209a and 209b are assembled with each other so that a part of the second end portion 209ab and a part of the fourth end portion 209bb may overlap each other in a vertical direction, and the assembling operation may be performed by compressing the substrate members 209a and 209b or by using an adhesive. Accordingly, the exposed portion of second end portion 209ab defined by the fourth end portion and the first end portion 209aa may form the recess region 102.

FIG. 12 is a cross-sectional view of a substrate 300 in which the recess region 102 is formed, according to another embodiment of the present invention.

Referring to FIG. 12, the substrate 300 includes a fifth substrate member 309a and a sixth substrate member 309b, which are assembled with each other to form the recess region 102. The fifth substrate member 309a has a fifth end portion 309aa having a fifth height H5 and a sixth end portion 309ab having a sixth height H6 that is lower than the fifth height H5. The sixth end portion 309ab may be formed by chemically etching or mechanically processing a part of the fifth substrate member 309a. In addition, the sixth substrate member 309b has a seventh end portion 309ba having a seventh height H7 and an eighth end portion 309bb having an eighth height H8 that is lower than the seventh height H7. The eighth end portion 309bb may be formed by chemically etching or mechanically processing a part of the sixth substrate member 309b. In addition, the fifth height H5 and the seventh height H7 may be equal to each other, and the sixth height H6 and the eighth height H8 may be equal to each other. The fifth and sixth substrate members 309a and 309b are assembled with each other so that a part of the sixth end portion 309ab and a part of the eighth end portion 309bb face each other, and the assembling operation may be performed by compressing the fifth and sixth substrate members 309a and 309b or by using an adhesive. Accordingly, the sixth end portion 309bb and the eighth end portion 309ab may together form the recess region 102.

According to a stack-type SSD of the present invention, a passive electronic element, a control semiconductor chip, and a buffer memory semiconductor chip are mounted in a recess region of a substrate, and a non-volatile memory semiconductor chip may be stacked on the substrate to overlap these elements. Accordingly, the size of the stack-type SSD may be reduced. In addition, since a length of a wire may be reduced, an operating speed of the stack-type SSD may be increased, a leakage current may be reduced, a power consumption of the stack-type SSD may be reduced, and fabrication costs of the stack-type SSD may be also reduced.

The foregoing is illustrative of exemplary embodiments and is not to be construed as limiting thereof. Although exemplary embodiments have been described, those of ordinary skill in the art will readily appreciate that many modifications are possible in the exemplary embodiments without materially departing from the novel teachings and advantages of the exemplary embodiments. Accordingly, all such modifications are intended to be included within the scope of the claims. Exemplary embodiments are defined by the following claims, with equivalents of the claims to be included therein.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A stack-type solid-state drive (SSD) comprising:
a substrate including one or more recess regions;
one or more passive electronic elements mounted in the one or more recess regions;
one or more control semiconductor chips mounted in the one or more recess regions;
one or more non-volatile memory semiconductor chips mounted on a first surface of the substrate so as to overlap the one or more passive electronic elements, the one or more control semiconductor chips, or all the passive electronic elements and the control semiconductor chips; and
an external connection terminal located on a side of the substrate.

2. The stack-type SSD of claim 1, further comprising one or more buffer memory semiconductor chips mounted in the one or more recess regions.

3. The stack-type SSD of claim 2, wherein the one or more buffer memory semiconductor chips comprise a dynamic random access memory (DRAM), a static random access memory (SRAM), or both of the DRAM and SRAM.

4. The stack-type SSD of claim 1, wherein at least some of the one or more passive electronic elements and the one or more control semiconductor chips are mounted in different recess regions from each other among the one or more recess regions.

5. The stack-type SSD of claim 2, wherein at least some of the one or more passive electronic elements, the one or more control semiconductor chips, and the one or more buffer memory semiconductor chips are mounted in different recess regions from each other among the one or more recess regions.

6. The stack-type SSD of claim 1, wherein the one or more recess regions further comprise a first wiring pattern formed in the recess regions, and the one or more passive electronic elements, the one or more control semiconductor chips, or all the passive electronic elements and the control semiconductor chips are electrically connected to the first wiring pattern via a first connection member.

7. The stack-type SSD of claim 6, wherein the first connection member comprises a bonding wire, a solder ball, a flip-chip bonding member, a bump, or a conductive via.

8. The stack-type SSD of claim 6, wherein the first connection member has a height so as not to protrude from the one or more recess regions.

9. The stack-type SSD of claim 1, wherein the substrate further comprises a second wiring pattern formed in the first surface, and the one or more non-volatile memory semiconductor chips are electrically connected to the second wiring pattern via a third connection member.

10. The stack-type SSD of claim 9, wherein the third connection member comprises a bonding wire, a solder ball, a flip-chip bonding member, a bump, or a conductive via.

11. The stack-type SSD of claim 1, wherein the one or more non-volatile memory semiconductor chips are semiconductor dies or semiconductor packages.

12. The stack-type SSD of claim 1, wherein the one or more non-volatile memory semiconductor chips are NAND flash memories, phase-change random access memories (PRAMs), resistive RAMs (RRAMs), ferroelectric RAMs (FeRAMs), or magnetic RAMs (MRAMs).

13. The stack-type SSD of claim 1, wherein the one or more non-volatile memory semiconductor chips comprise a plurality of non-volatile memory semiconductor chips which are stacked.

14. The stack-type SSD of claim 1, further comprising one or more additional non-volatile memory semiconductor chips mounted in the one or more recess regions.

15. The stack-type SSD of claim 1, wherein the substrate has a multi-layered structure.

16. The stack-type SSD of claim 1, wherein the substrate comprises an epoxy resin, a polyimide resin, a bismaleimide triazine (BT) resin, frame retardant (FR)-4, FR-6, ceramic, silicon, or glass.

17. The stack-type SSD of claim 1, wherein the external connection terminal is a serial advanced technology attachment (SATA), a parallel advanced technology attachment (PATA), a universal serial bus (USB), or an integrated drive electronics (IDE).
